(19) United States
(12) Patent Application Publication
(10) Pub. No.: US 2025/0318192 A1
(43) Pub. Date: Oct. 9, 2025

(54) SEMICONDUCTOR DEVICE AND METHOD FOR MANUFACTURING SEMICONDUCTOR DEVICE

(71) Applicant: Japan Display Inc., Tokyo (JP)

(72) Inventors: Akihiro HANADA, Tokyo (JP); Motochika YUKAWA, Tokyo (JP); Takuo KAITOH, Tokyo (JP)

(73) Assignee: Japan Display Inc., Tokyo (JP)

(21) Appl. No.: 19/091,830

(22) Filed: Mar. 27, 2025

(30) Foreign Application Priority Data
Apr. 4, 2024 (JP) 2024-060736

(51) Int. Cl. H10D 30/67; H10D 30/01; H10D 62/60; H10D 86/40; H10D 86/60

(52) U.S. Cl. CPC H10D 30/6734; H10D 30/0312; H10D 30/6755; H10D 30/6757; H10D 62/60; H10D 86/423; H10D 86/60; H10D 86/471

(57) ABSTRACT

A semiconductor device includes a first gate electrode, a first gate insulating layer, an oxide semiconductor layer, a second gate insulating layer having first and second apertures, a second gate electrode extending in a first direction, a first electrode in contact with the oxide semiconductor layer in the first aperture and a second electrode in contact with the oxide semiconductor layer in the second aperture, wherein the second gate electrode overlaps the oxide semiconductor layer in a first region in a plan view, the first electrode is in contact with the oxide semiconductor layer in a second region in the plan view, a width of the second gate electrode in a second direction is 2 μm or less in a cross-sectional view, and a distance between the first region and the second region in the second direction is 2 μm or less in the cross-sectional view.

### CROSS-REFERENCE TO RELATED APPLICATION

This application claims the benefit of priority to Japanese Patent Application No. 2024-060736, filed on Apr. 4, 2024, the entire contents of which are incorporated herein by reference.

### FIELD

One embodiment of the present invention relates to a semiconductor device and a method of manufacturing the semiconductor device.

### BACKGROUND

Recently, in place of amorphous silicon, low-temperature polysilicon, and single-crystal silicon, a transistor in which an oxide semiconductor is used as a channel has been developed (for example, Japanese Laid-Open Patent Publication No. 2014-146819 and Japanese Laid-Open Patent Publication No. 2015-159315). A transistor in which an oxide semiconductor is used as a channel is formed by a simple structure and a low-temperature process similar to a transistor in which amorphous silicon is used as a channel. It is known that a transistor in which an oxide semiconductor is used for a channel has higher mobility than a transistor in which amorphous silicon is used for a channel, and exhibits a very low off-state current.

In recent years, a size of pixels in a display device has been reduced. With the reduction of the pixel size, reduction of a wiring width and a transistor size has been studied. However, since there is a limit to the reduction, it is difficult to obtain a sufficient aperture ratio due to an arrangement of a metal layer and a semiconductor layer constituting a pixel circuit. Therefore, even if the transistor size is small, a transistor in which an oxide semiconductor layer is used as a channel has been developed for use as a transistor of a pixel circuit, which can obtain sufficient characteristics for driving of the pixel circuit.

When the size of the transistor is reduced, an abnormality may occur in the transistor characteristics due to an influence of a method for manufacturing the transistor. In particular, in the characteristics of the transistor, it is difficult to achieve both initial characteristics and reliability in a stress test. Therefore, in many transistors, initial characteristics and reliability are in a trade-off relationship. For example, in a transistor having a top gate structure in which an oxide semiconductor layer is used as a channel, the initial characteristics and results of the stress test are affected by the film quality of the insulating layer arranged above the gate electrode. An initial characteristic abnormality of the transistor and characteristic variation in a reliability test adversely affect operations of the pixel circuit in the display device.

### SUMMARY

A semiconductor device according to an embodiment of the present invention includes: a first gate electrode; a first gate insulating layer above the first gate electrode; an oxide semiconductor layer above the first gate insulating layer; a second gate insulating layer above the oxide semiconductor layer and having a first aperture and a second aperture reaching the oxide semiconductor layer; a second gate electrode above the second gate insulating layer and extending in a first direction; a first electrode in contact with the oxide semiconductor layer in the first aperture; and a second electrode in contact with the oxide semiconductor layer in the second aperture, wherein the second gate electrode overlaps the oxide semiconductor layer in a first region, the first electrode is in contact with the oxide semiconductor layer in a second region, a width of the second gate electrode in a second direction intersecting the first direction is 2 μm or less in a cross sectional view, and a distance between the first region and the second region in the second direction is 2 μm or less in the cross sectional view.

A method for manufacturing a semiconductor device according to an embodiment of the present invention includes: forming a first gate electrode above a substrate; forming a first gate insulating layer above the first gate electrode; forming an oxide semiconductor layer above the first gate insulating layer; forming a second gate insulating layer above the oxide semiconductor layer; forming a second gate electrode above the second gate insulating layer, the second gate electrode extending in a first direction; implanting an impurity to the oxide semiconductor layer through the second gate insulating layer from above the second gate electrode; forming a first aperture and a second aperture in the second gate insulating layer, the first aperture and the second aperture reaching the oxide semiconductor; and forming a first electrode in contact with the oxide semiconductor in the first aperture and a second electrode in contact with the oxide semiconductor in the second aperture, wherein a width of the second gate electrode in a second direction intersecting the first direction is 2 μm or less in a cross sectional view, and a distance between the first region and the second region in the second direction is 2 μm or less in the cross sectional view.

### BRIEF DESCRIPTION OF DRAWINGS

FIG. 1 is a cross-sectional view showing an outline of a display device according to an embodiment of the present invention.

FIG. 2 is a plan view showing an outline of a display device according to an embodiment of the present invention.

FIG. 3 is a plan view for explaining a layout of each layer in a display device according to an embodiment of the present invention.

FIG. 4 is a plan view for explaining a layout of each layer in a display device according to an embodiment of the present invention.

FIG. 5 is a plan view for explaining a layout of each layer in a display device according to an embodiment of the present invention.

FIG. 6 is a plan view for explaining a layout of each layer in a display device according to an embodiment of the present invention.

FIG. 7 is a plan view for explaining a layout of each layer in a display device according to an embodiment of the present invention.

FIG. 8 is a plan view for explaining a layout of each layer in a display device according to an embodiment of the present invention.

FIG. 9 is a plan view for explaining a layout of each layer in a display device according to an embodiment of the present invention.

FIG. 10 is a plan view for explaining a layout of each layer in a display device according to an embodiment of the present invention.

FIG. 11 is a plan view for explaining a layout of each layer in a display device according to an embodiment of the present invention.

FIG. 12 is a plan view for explaining a layout of each layer in a display device according to an embodiment of the present invention.

FIG. 13 is a plan view for explaining a layout of each layer in a display device according to an embodiment of the present invention.

FIG. 14 is a cross-sectional view showing a structure of a semiconductor device according to an embodiment of the present invention.

FIG. 15 is a diagram showing electrical characteristics of a semiconductor device according to an embodiment of the present invention.

FIG. 16 is a diagram showing electrical characteristics of a semiconductor device according to an embodiment of the present invention.

FIG. 17 is a flowchart showing a method for manufacturing a semiconductor device according to an embodiment of the present invention.

FIG. 18 is a cross-sectional view showing a structure of a semiconductor device according to a modification of an embodiment of the present invention.

FIG. 19 is a cross-sectional view showing the structure of the semiconductor device according to the modification of an embodiment of the present invention.

FIG. 20 is a plan view showing an outline of a display device according to an embodiment of the present invention.

FIG. 21 is a block diagram showing a circuit configuration of a display device according to an embodiment of the present invention.

FIG. 22 is a circuit diagram showing a pixel circuit of a display device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the shown shapes are merely examples, and do not limit the interpretation of the present invention. In the present specification and the drawings, the same components as those already described with respect to the drawings already described are denoted by the same reference signs, and a detailed description thereof may be omitted as appropriate.

In each embodiment of the present invention, a direction from a substrate toward an oxide semiconductor layer is referred to as “above” or “upper.” Conversely, a direction from the oxide semiconductor layer toward the substrate is referred to as “under” or “lower.” As described above, although for convenience of explanation, the term “upper” or “lower” is used for description, for example, the upper and lower relationships between the substrate and the oxide semiconductor layer may be arranged in a direction different from that shown in the figure. In the following description, for example, the expression “oxide semiconductor layer above the substrate” merely describes the vertical relationship between the substrate and the oxide semiconductor layer as described above, and other members may be disposed between the substrate and the oxide semiconductor layer. “Upper” or “lower” means a stacking order in a structure in which a plurality of layers are stacked, and in a case where the stacking order is expressed as “a pixel electrode above the transistor,” the positional relationship may be such that the transistor and the pixel electrode do not overlap each other in a plan view. On the other hand, the expression “pixel electrode vertically above the transistor” means a positional relationship in which the transistor and the pixel electrode overlap each other in the plan view.

A “display device” refers to a structure that displays an image using an electro-optical layer. For example, the term “display device” may refer to a display panel including an electro-optical layer, or may refer to a structure in which another optical member (for example, a polarizing member, a backlight, a touch panel, or the like) is attached to a display cell. An “electro-optical layer” may include a liquid crystal layer, an electroluminescent (EL) layer, an electrochromic (EC) layer, or an electrophoretic layer, unless there is a technical inconsistency. Therefore, although an embodiment to be described later will be described by exemplifying a liquid crystal display device including a liquid crystal layer as a display device, the structure of the present embodiment can be applied to a display device including another electro-optical layer described above.

As used herein, the phrase “a comprises A, B, or C,” “a comprises any of A, B, and C,” “α comprises one selected from the group consisting of A, B, and C,” and the like does not exclude cases where α comprises a plurality of combinations of A to C unless otherwise indicated. Furthermore, these expressions do not exclude the case where α includes other elements.

In addition, the following embodiments can be combined with each other as long as there is no technical inconsistency.

An object of one embodiment of the present invention is to realize a semiconductor device that does not adversely affect circuit operation even in a fine pixel circuit.

### 1. First Embodiment

### [1-1. Configuration of Display Device 10]

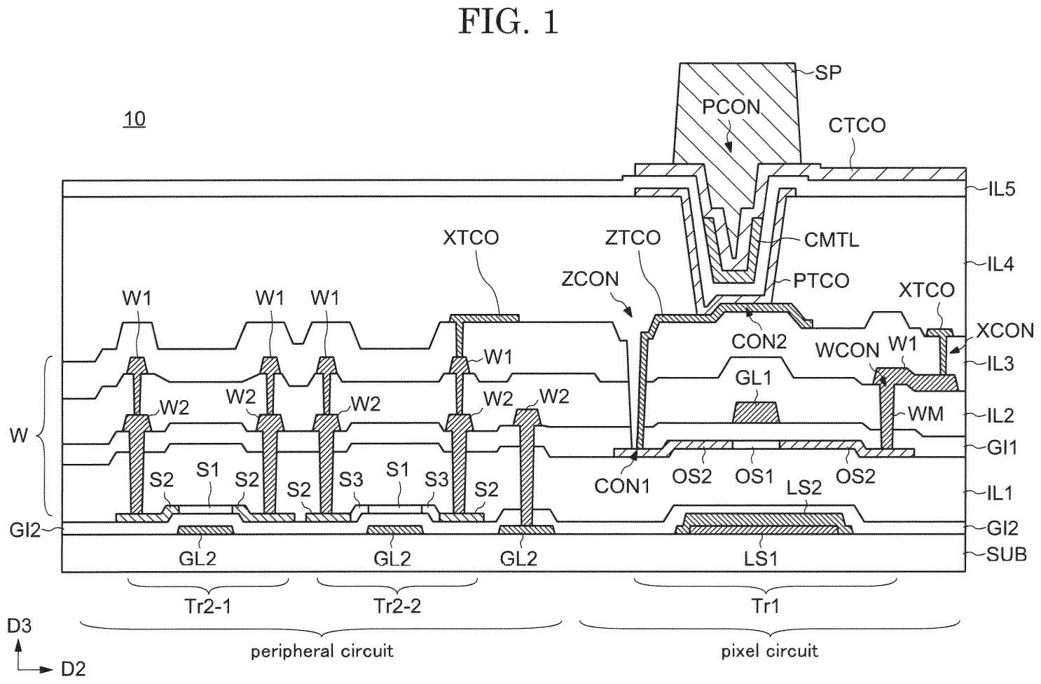

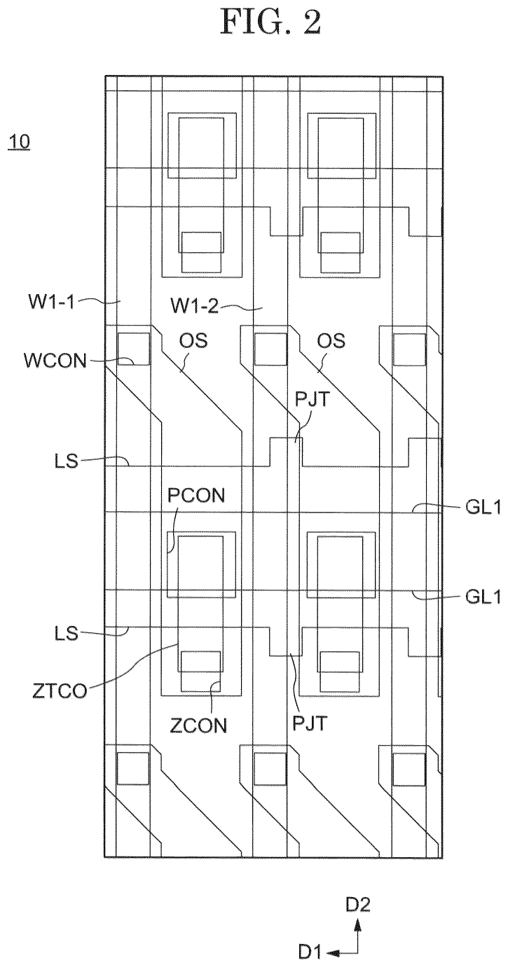

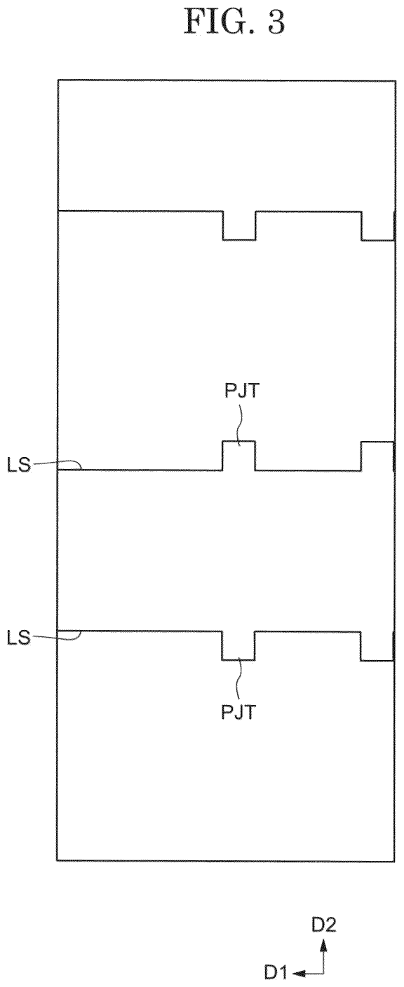

A configuration of a display device 10 according to an embodiment of the present invention will be described with reference to FIG. 1 to FIG. 13. FIG. 1 is a cross-sectional view showing an outline of a display device according to an embodiment of the present invention. FIG. 2 is a plan view showing an outline of a display device according to an embodiment of the present invention. FIG. 3 to FIG. 13 are plan views for explaining a layout of each layer in a display device according to an embodiment of the present invention. The cross-sectional view of FIG. 1 is a cross-sectional view for explaining the layer structure of the display device 10, and may not strictly coincide with the plan view of FIG. 2.

As shown in FIG. 1, the display device 10 is arranged above a substrate SUB. The display device 10 includes a transistor Tr1, a transistor Tr2 (Tr2-1 and Tr2-2), a wiring W, a pixel electrode PTCO, a common auxiliary electrode CMTL, and a common electrode CTCO. TCO is an abbreviation for Transparent Conductive Oxide. The transistor Tr1 is a semiconductor device included in a pixel circuit (pixel circuit) of the display device 10. The transistor Tr2 is a device included in a peripheral circuit. As will be described in detail later, the peripheral circuit is a circuit that drives the pixel circuit. In the following explanation, the “semiconductor device” may include only a configuration of the transistor Tr1, and may include both configurations of the transistors Tr1 and Tr2.

### [1-2. Configuration of Transistor Tr1]

The transistor Tr1 includes a gate electrode LS (LS1 and LS2), gate insulating layers GI2 and IL1, an oxide semiconductor layer OS (OS1 and OS2), a gate insulating layer GI1, a gate electrode GL1, a connection electrode WM, a connection electrode ZTCO, and a wiring XTCO. The gate electrode LS is arranged above the substrate SUB. The gate insulating layers GI2 and IL1 are arranged above the gate electrode LS. The oxide semiconductor layer OS is arranged above the gate insulating layer IL1. The gate insulating layer GI1 is arranged above the oxide semiconductor layer OS. The gate electrode GL1 is arranged above the gate insulating layer GI1. In the present embodiment, although a dual-gate transistor is exemplified in which the gate electrode LS is arranged below the oxide semiconductor layer OS and the gate electrode GL1 is arranged above the oxide semiconductor layer OS, a top-gate transistor in which only the gate electrode GL1 is provided may be used.

In the present embodiment, the gate electrodes LS1 and LS2 are provided as the gate electrode LS. However, the gate electrode LS may be formed only of the gate electrode LS1 or only of LS2. In a plan view, the gate electrode LS is arranged in a region where the gate electrode GL1 and the oxide semiconductor layer OS overlap each other. That is, in the plan view, the gate electrode LS is arranged in a region overlapping the oxide semiconductor layer OS1. The gate electrode LS is supplied with, for example, the same voltage as the gate electrode GL1. However, the gate electrode LS may be supplied with a voltage that differs from the gate electrode GL1. The gate electrode LS also functions as a light shielding layer, and suppresses light incident from the substrate SUB side from reaching the oxide semiconductor layer OS1.

In the present embodiment, although a configuration in which the oxide semiconductor layer OS is in contact with the gate insulating layer IL1 has been exemplified, the configuration is not limited to this configuration. For example, a metallic oxide layer may be arranged between the oxide semiconductor layer OS and the gate insulating layer IL1. For example, a metal oxide containing aluminum as a main component may be used as the metal oxide layer. Specifically, aluminum oxide may be used as the metal oxide layer. In this case, the metal oxide layer may be arranged in the same region as the gate insulating layer IL1, and may be processed into the same pattern as the oxide semiconductor layer OS.

The oxide semiconductor layer OS includes a polycrystalline structure, an amorphous structure, or a structure in which a polycrystalline structure and an amorphous structure are mixed. The oxide semiconductor layer OS includes oxide semiconductor layers OS1 and OS2. The oxide semiconductor layer OS1 is an oxide semiconductor layer in a region overlapping the gate electrode GL1 in the plan view. The oxide semiconductor layer OS1 functions as a semiconductor layer, and is switched between a conductive state and a non-conductive state in accordance with a voltage supplied to the gate electrode GL1. That is, the oxide semiconductor layer OS1 functions as a channel of the transistor Tr1. The oxide semiconductor layer OS2 functions as a conductive layer. The oxide semiconductor layers OS1 and OS2 are layers formed from the same oxide semiconductor layer. For example, the oxide semiconductor layer OS2 is an oxide semiconductor layer that has reduced resistance by implanting an impurity into a layer having the same physical properties as the oxide semiconductor layer OS1.

An insulating layer IL2 is arranged above the gate electrode GL1. A wiring W1 is arranged above the insulating layer IL2. The wiring W1 is connected to the oxide semiconductor layer OS2 via the connection electrode WM arranged inside an opening WCON arranged in the insulating layer IL2 and the gate insulating layer GI1. The connection electrode WM is in contact with the oxide semiconductor layer OS at a bottom of the opening WCON. The wiring W1 and the connection electrode WM are metallic layers and are the same layer. A data signal related to gradation of the pixel is transmitted to the wiring W1. An insulating layer IL3 is arranged above the insulating layer IL2 and the wiring W1. The connection electrode ZTCO and the wiring XTCO are in contact with an upper surface of the insulating layer IL3 above the insulating layer IL3.

The connection electrode ZTCO is connected to the oxide semiconductor layer OS2 via openings ZCON arranged in the insulating layers IL3 and IL2 and the gate insulating layer GI1. The contact electrode ZTCO is in contact with the oxide semiconductor layer OS2 in a contact region CON1 at a bottom of the opening ZCON. The wiring XTCO is connected to the wiring W1 via an opening XCON arranged in the insulating layer IL3. The connection electrode ZTCO and the wiring XTCO are transparent conductive layers. As described above, the gate electrode GL1, the wiring W1, the connection electrode WM, the connection electrode ZTCO, and the wiring XTCO are arranged above the oxide semiconductor layer OS.

The wiring XTCO is arranged in the same layer as the connection electrode ZTCO and is separated from the connection electrode ZTCO. Although a material of the connection electrode ZTCO is the same as a material of the wiring XTCO, the crystallinity of a part of the connection electrode ZTCO differs from the crystallinity of the wiring XTCO. For example, even in the ZTCO where the connection electrodes and the wiring XTCO are both formed by the same process, the crystallinity of a part of ITO used as the connection electrode differs from the crystallinity of ITO used as the wiring XTCO. Different crystallinities include different crystal structures, different parameters such as lattice constants even if the crystal structures are the same, and the like. When transparent conductive layers having different crystallinity are observed with an optical microscope, the colors of these transparent conductive layers are different. That is, refractive indices of these transparent conductive layers are different.

The connection electrode ZTCO is divided into a contact region and a non-contact region in the plan view. The contact region includes a region where the connection electrode ZTCO is in contact with the oxide semiconductor layer OS. The non-contact region is a region other than the contact region. The crystallinity of the connection electrode ZTCO in the contact region differs from the crystallinity of the connection electrode ZTCO in the non-contact region.

For example, if a transparent conductive layer such as an ITO layer is formed in contact with a semiconductor layer such as a silicon layer, a surface of the semiconductor layer is oxidized by process gases and oxygen ions during ITO film formation. Since the oxide layer formed on the surface of the semiconductor layer has high resistance, contact resistance between the semiconductor layer and the transparent conductive layer increases. As a result, a defect occurs in an electrical contact between the semiconductor layer and the transparent conductive layer.

On the other hand, in the case where the connection electrode ZTCO is formed so as to be in contact with the oxide semiconductor layer OS, a high-resistance oxide layer as described above is not formed on the oxide semiconductor layer OS.

As described above, crystallization of the connection electrode ZTCO during film formation is considered to reduce the oxide semiconductor layer OS in regions of the oxide semiconductor layer OS in contact with the connection electrode ZTCO. Therefore, it is considered that carrier concentration on the surface of the oxide semiconductor layer OS is increased, and contact resistance between the oxide semiconductor layer OS and the connection electrode ZTCO is reduced.

An insulating layer IL4 is arranged above the connection electrode ZTCO. The insulating layer IL4 alleviates a step formed by a structure arranged below the insulating layer IL4. The insulating layer IL4 may be referred to as a planarization film. The pixel electrode PTCO is arranged above the insulating layer IL4. The pixel electrode PTCO is connected to the connection electrode ZTCO via an opening PCON arranged in the insulating layer IL4. A region where the connection electrode ZTCO and the pixel electrode PTCO are in contact with each other is referred to as a contact region CON2. In the plan view, the contact region CON2 overlaps the gate electrode GL1. The pixel electrode PTCO is a transparent conductive layer.

An insulating layer IL5 is arranged above the pixel electrode PTCO. The common auxiliary electrode CMTL and the common electrode CTCO are arranged above the insulating layer IL5. That is, the pixel electrode PTCO faces the common electrode CTCO via the insulating layer IL5. The common electrode CTCO is connected to the common auxiliary electrode CMTL in the opening PCON. The common auxiliary electrode CMTL and the common electrode CTCO have different planar patterns, which will be described later. The common electrode CMTL is a metal layer. The common electrode CTCO is a transparent conductive layer. Electric resistance of the common auxiliary electrode CMTL is lower than electric resistance of the common electrode CTCO. The common auxiliary electrode CMTL also functions as a light shielding layer. For example, the common auxiliary electrode CMTL blocks light from neighboring pixels, thereby suppressing the occurrence of color mixing. A spacer SP is arranged above the common electrode CTCO.

The spacer SP is provided for some of the pixels. For example, the spacer SP may be provided for any one of a blue pixel, a red pixel, and a green pixel. However, the spacer SP may be provided in all the pixels. The height of the spacer SP is half the height of a cell gap. A spacer is also provided on a counter substrate, and the spacer of the counter substrate and the spacer SP overlap each other in the plan view.

In the above configuration, the gate electrode LS may be referred to as a “first gate electrode.” The gate insulating layers GI2 and IL1 may be referred to as “first gate insulating layers.” The gate insulating layer GI1 may be referred to as a “second gate insulating layer.” The gate electrode GL1 may be referred to as a “second gate electrode.” The insulating layer IL2 may be referred to as a “first insulating layer.” The insulating layer IL3 may be referred to as a “second insulating layer.” The opening WCON may be referred to as a “first opening.” The opening ZCON may be referred to as a “second opening.” The wiring W1 and the connection electrode WM may be referred to as a “first electrode.” The connection electrode ZTCO may be referred to as a “second electrode.”

### [1-3. Configuration of Transistor Tr2]

The transistor Tr2 includes the p-type transistor Tr2-1 and the n-type transistor Tr2-2.

Each of the p-type transistor Tr2-1 and the n-type transistor Tr2-2 includes a gate electrode GL2, a gate insulating layer GI2, and a semiconductor layer S (S1 to S3). The gate electrode GL2 faces the semiconductor layer S. The gate insulating layer GI2 is arranged between the semiconductor layer S and the gate electrode GL2. In the present embodiment, although a bottom-gate transistor in which the gate electrode GL2 is arranged closer to the substrate SUB than the semiconductor layer S is exemplified, a top-gate transistor in which the positional relationship between the semiconductor layer S and the gate electrode GL2 is reversed may be used.

The semiconductor layer S of the p-type transistor Tr2-1 includes semiconductor layers S1 and S2. The semiconductor layer S of the n-type transistor Tr2-2 includes semiconductor layers S1, S2, and S3. The semiconductor layer S1 is a semiconductor layer in a region overlapping the gate electrode GL2 in the plan view. The semiconductor layer S1 serves as a channel for the transistors Tr2-1 and Tr2-2. The semiconductive layer S2 functions as a conductive layer. The semiconductor layer S3 functions as a conductive layer having a higher resistance than the semiconductor layer S2. The semiconductor layer S3 attenuates hot carriers that penetrate toward the semiconductor layer S1, thereby suppressing hot carrier degradation.

The gate insulating layer IL1 and the gate insulating layer GI1 are arranged above the semiconductor layer S. In the transistor Tr2, the gate insulating layer GI1 simply functions as an interlayer film. A wiring W2 is arranged above the insulating layer. The wiring W2 is connected to the semiconductor layer S2 through openings arranged in the gate insulating layer IL1 and the gate insulating layer GI1. The insulating layer IL2 is arranged above the wiring W2. The wiring W1 is arranged above the insulating layer IL2. The wiring W1 is connected to the wiring W2 through an opening arranged in the insulating layer IL2. The insulating layer IL3 is arranged above the wiring W1. The wiring XTCO is arranged above the insulating layer IL3. The wiring XTCO is connected to the wiring W1 through an opening arranged in the insulating layer IL3.

The gate electrode GL2 and the gate electrode LS2 are the same layers. The wiring W2 and the gate electrode GL1 are the same layer. The “same layer” means that a plurality of members are formed by patterning one layer.

### [1-4. Plane Layout of Display Device 10]

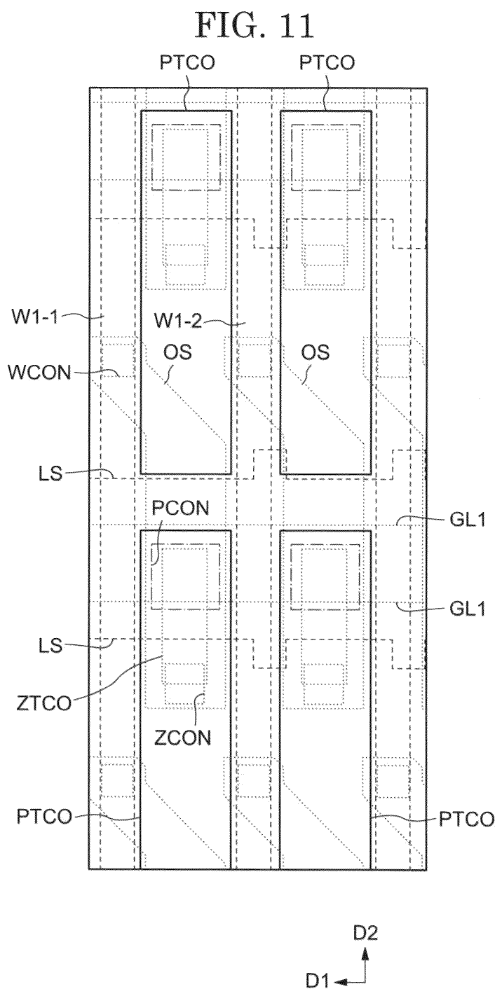

A planar layout of pixels of the display device 10 will be described with reference to FIG. 2 to FIG. 13. In FIG. 2, the pixel electrode PTCO, the common auxiliary electrode CMTL, the common electrode CTCO, and the spacer SP are omitted. The planar layouts of the pixel electrode PTCO, the common auxiliary electrode CMTL, and the common electrode CTCO are shown in FIG. 11 to FIG. 13, respectively.

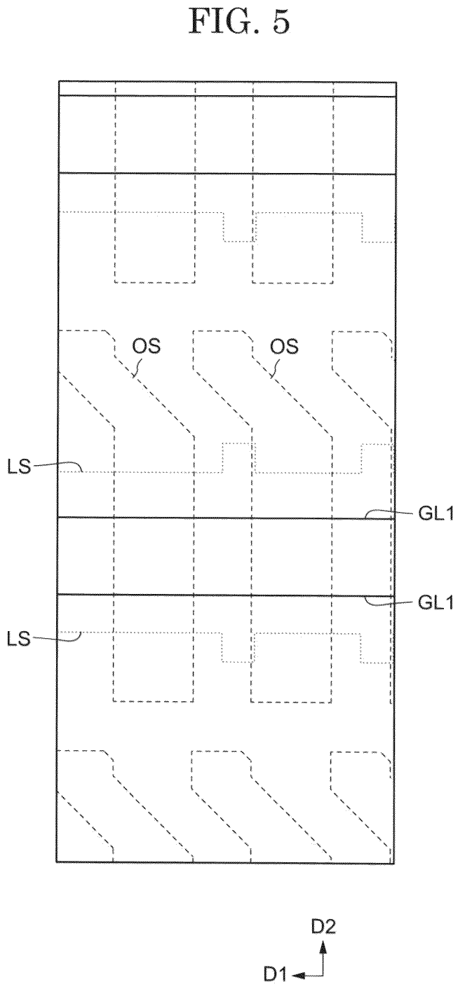

As shown in FIG. 2 and FIG. 3, the gate electrode LS extends in a direction D1. Shapes of the gate electrode LS differ depending on the pixels. In the present embodiment, a protrusion PJT protruding in a direction D2 is provided from a part of the gate electrode LS extending in the direction D1. As shown in FIG. 5, the gate electrode LS is arranged in a region including a region where the gate electrode GL1 and the oxide semiconductor layer OS overlap each other in the plan view. Further, the gate electrode GL1 may also be referred to as a “gate line.”

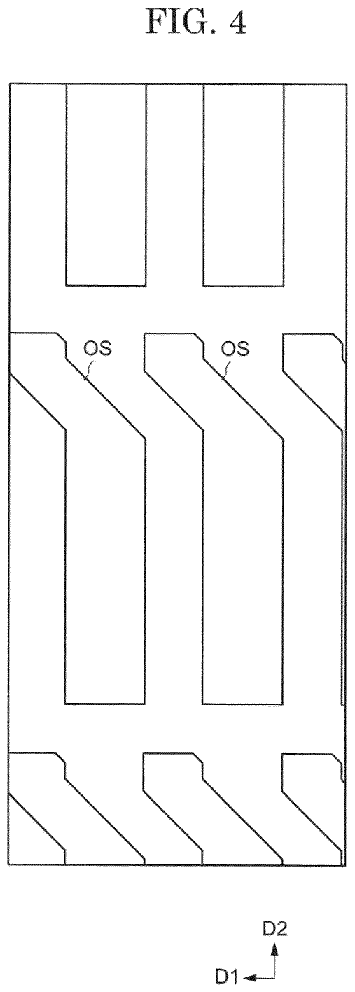

As shown in FIG. 2, FIG. 4, and FIG. 5, the oxide semiconductor layer OS extends in the direction D2. The gate electrode GL1 extends in the direction D1 so as to intersect with the oxide semiconductor layer OS. A pattern of the gate electrode GL1 is arranged inside a pattern of the gate electrode LS. In other words, the oxide semiconductor layer OS is formed in an elongated shape (a shape having a long side) intersecting the gate electrode GL1.

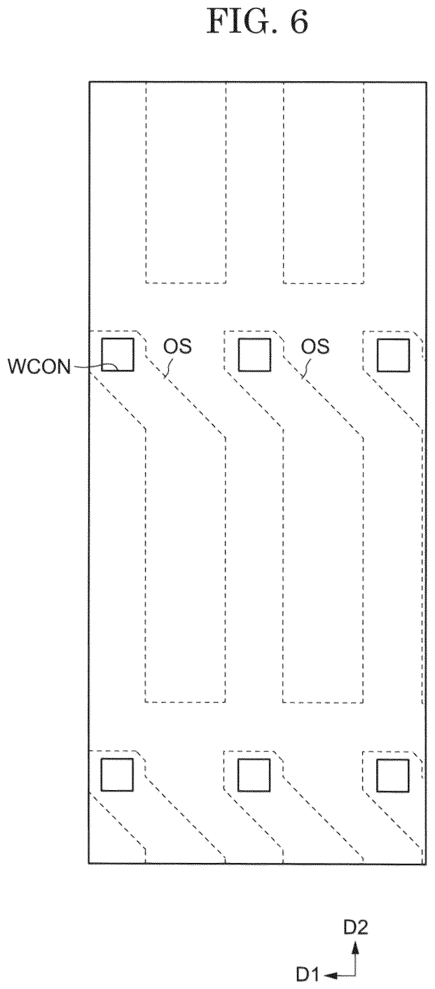

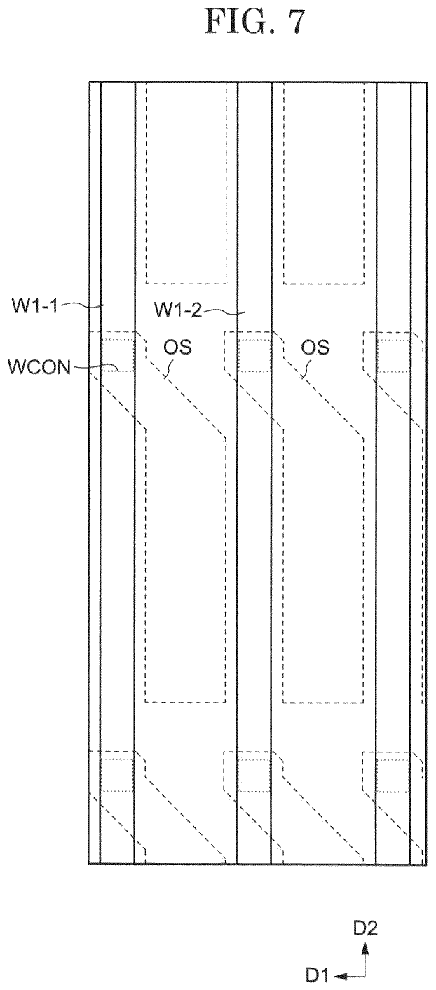

As shown in FIG. 2, FIG. 6, and FIG. 7, the opening WCON is arranged in a region overlapping the wiring W1 (W1-1 and W1-2) in the vicinity of an upper end of a pattern of the oxide semiconductor layer OS. The oxide semiconductor layer OS may be formed in the direction D2 between neighboring lines W1 (W1-1 and W1-2). The remaining part of the pattern of the oxide semiconductor layer OS extends from a main part toward the region of the opening WCON in a direction oblique to the direction D1 and the direction D2.

As shown in FIG. 2 and FIG. 7, a plurality of wirings W1 extend in the direction D2. In the case where adjacent wirings W1 need to be described separately, the adjacent wirings W1 are referred to as the wiring W1-1 and the wiring W1-2. A main part of the oxide semiconductor layer OS extends in the direction D2 between the wiring W1-1 and the wiring W1-2 and intersects the gate electrode GL1. In other words, the oxide semiconductor layer OS is provided in an elongated shape in the direction D2, and is connected to the wiring W1-1 at one end portion in a longitudinal direction of the oxide semiconductor layer OS.

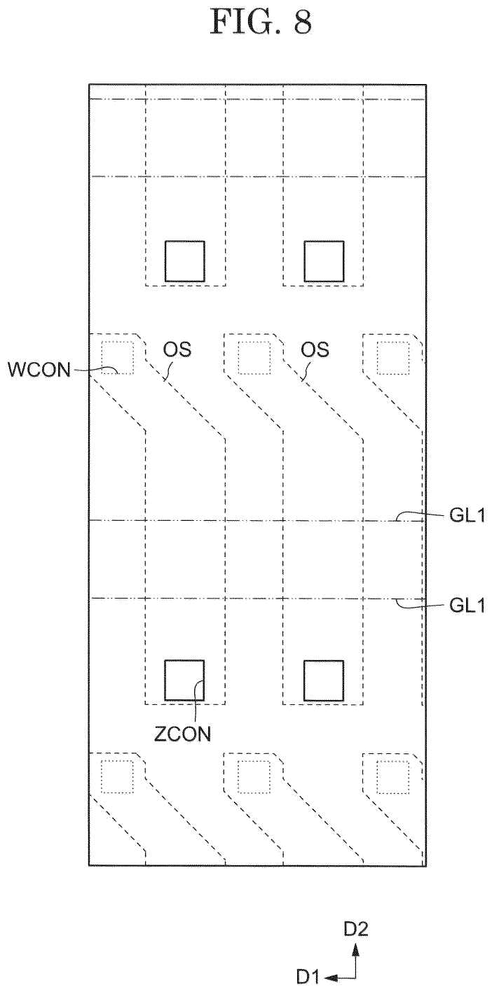

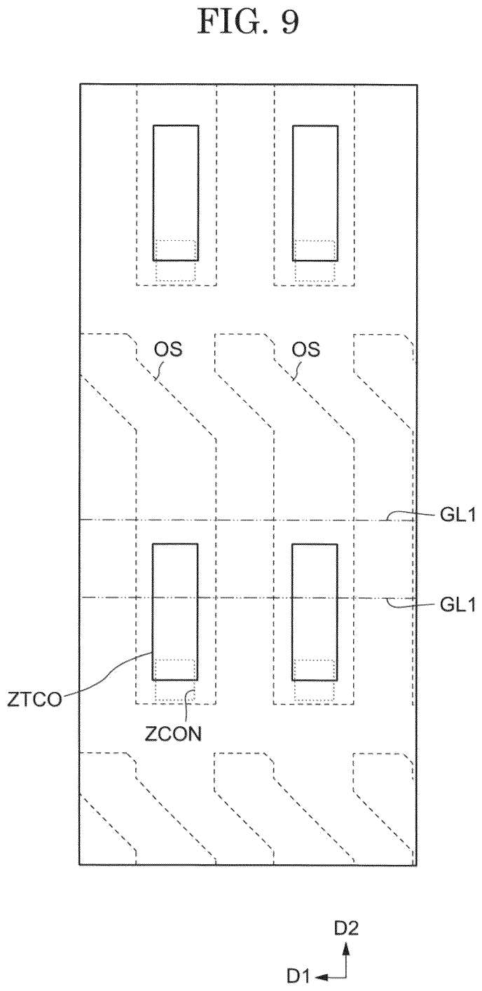

As shown in FIG. 2, FIG. 8, and FIG. 9, the opening ZCON is arranged in a vicinity of a lower end of the pattern of the oxide semiconductor layer OS. The opening ZCON is arranged in a region overlapping the pattern of the oxide semiconductor layer OS and not overlapping the gate electrode GL1. The opening ZCON is arranged in a region overlapping the connection electrode ZTCO. The connection electrode ZTCO overlaps the gate electrode GL1 and the oxide semiconductor layers OS between the wiring W1-1 and the wiring W1-2. Therefore, the connection electrode ZTCO is in contact with the oxide semiconductor layer OS in the opening ZCON that does not overlap the gate electrode GL1.

In other words, the oxide semiconductor layer OS is connected to the connection electrode ZTCO at the other end portion in the longitudinal direction of the oxide semiconductor layer OS. The connection electrode ZTCO is formed in an elongated shape extending in the direction D2 as in the case of the oxide semiconductor layer OS. In the direction D1, a width of the connection electrode ZTCO is smaller than a width of the oxide semiconductor layer OS.

As shown in FIG. 2, FIG. 7, and FIG. 8, the oxide semiconductor layer OS is in contact with the wiring W1 on the other side of the gate electrode GL1 from the opening ZCON. The opening ZCON does not overlap the gate electrode LS.

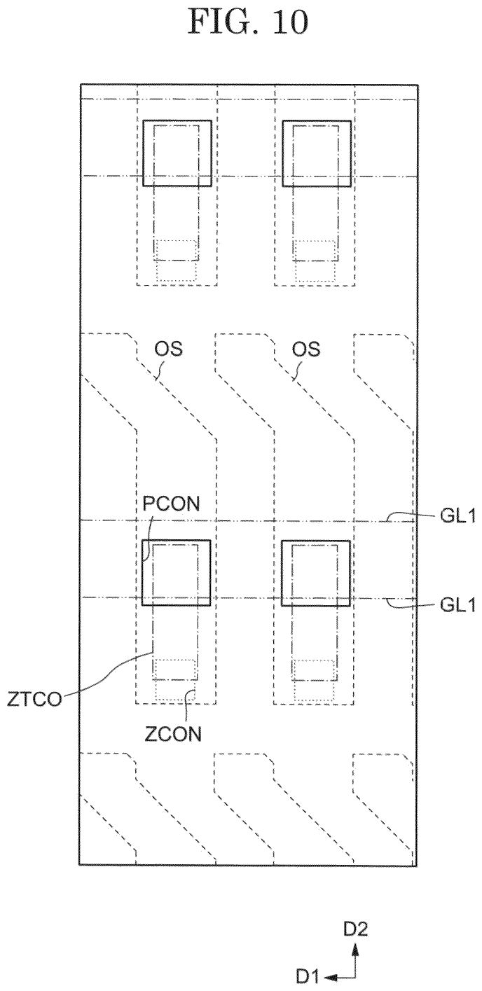

As shown in FIG. 2, FIG. 10, and FIG. 11, the opening PCON is arranged near an upper end of the connection electrode ZTCO. The opening PCON is arranged in a region overlapping a pattern of the gate electrode GL1 and a pattern of the connection electrode ZTCO. The opening PCON is arranged in a region overlapping the pixel electrode PTCO. The pixel electrode PTCO overlaps the gate electrode GL1, the oxide semiconductor layer OS, and the connection electrode ZTCO between the wiring W1-1 and the wiring W1-2. Therefore, the pixel electrode PTCO is in contact with the connection electrode ZTCO in the opening PCON overlapping the gate electrode GL1.

The pixel electrode PTCO extends in a light transmitting region described below. In other words, the pixel electrode PTCO is formed in an elongated shape extending in the direction D2 as in the case of the oxide semiconductor layer OS and the wiring W1-1. In the direction D1, a width of the pixel electrode PTCO in a portion where the opening PCON is arranged is larger than the width of the oxide semiconductor layer OS.

As shown in FIG. 11, the connection electrode ZTCO is formed in an elongated shape extending along the wiring W1-1. In the direction D1, a width of the opening PCON constituting the contact region CON2 is larger than the width of the connection electrode ZTCO. In the plan view, the entire connection electrode ZTCO overlaps the pixel electrode PTCO.

As shown in FIG. 11, the pixel electrodes PTCO are arranged in the direction D2. Among the pixels adjacent in the direction D2, one pixel may be referred to as a “first pixel,” and the other pixel may be referred to as a “second pixel.” For example, the first pixel is a pixel corresponding to an upper pixel electrode PTCO among the pixel electrodes PTCO aligned in the direction D2 in FIG. 11, and the second pixel is a pixel corresponding to a lower pixel electrode PTCO among the pixel electrodes PTCO aligned in the direction D2. In this case, the first pixel and the second pixel are supplied with pixel signals from the wiring W1-1.

In addition, the pixel electrodes PTCO are arranged in the direction D1. A pixel adjacent to the first pixel in the direction D1 is referred to as a “third pixel,” and a pixel adjacent to the second pixel in the direction D1 is referred to as a “fourth pixel.” The third pixel and the fourth pixel are adjacent to each other in the direction D2. The third pixel and the fourth pixel are supplied with pixel signals from the wiring W1-2 adjacent to the wiring W1-1.

As described above, each of the first pixel, the second pixel, the third pixel, and the fourth pixel includes the transistor Tr1 (pixel transistor), the connection electrode ZTCO, and the pixel electrode PTCO.

The transistor Tr1 includes the oxide semiconductor layer OS, the gate electrode GL1 facing the oxide semiconductor layer OS, and the gate insulating layer GI1 between the oxide semiconductor layer OS and the gate electrode GL1. The connection electrode ZTCO overlaps the gate electrode GL1 and the oxide semiconductor layer OS in the plan view, and is in contact with the oxide semiconductor layer OS in the opening ZCON that does not overlap the gate electrode GL1. The pixel electrode PTCO overlaps the gate electrode GL1, the oxide semiconductor layer OS, and the connection electrode ZTCO in the plan view, and is connected to the connection electrode ZTCO in the opening PCON that overlaps the gate electrode GL1.

The pixel electrode PTCO of the first pixel arranged on an upper side in FIG. 11 overlaps the oxide semiconductor layer OS of the first pixel and the oxide semiconductor layer OS of the second pixel arranged on a lower side of the first pixel in the plan view. The pixel electrode PTCO of the first pixel overlaps the oxide semiconductor layer OS of the fourth pixel in the plan view.

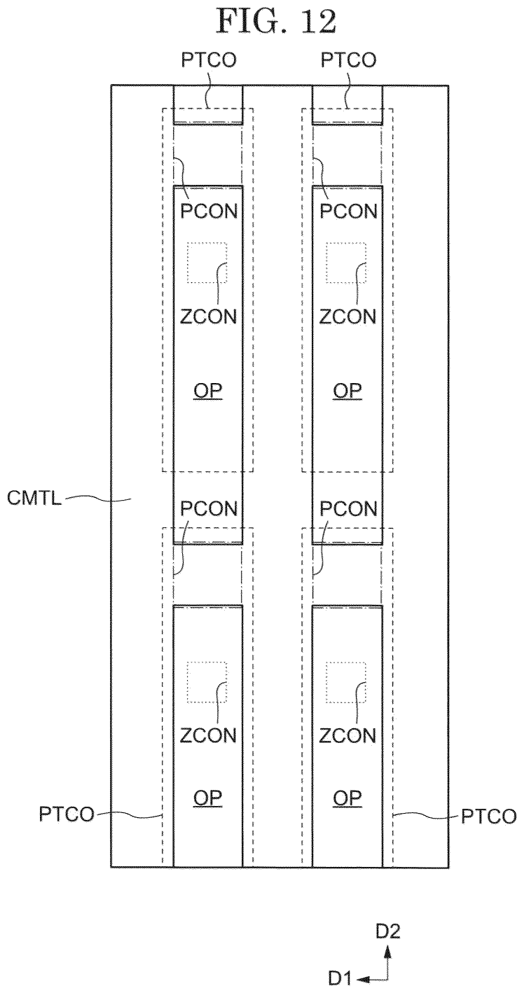

As shown in FIG. 12, the common auxiliary electrode CMTL is provided in a grid shape so as to surround the periphery of a pixel region. That is, the common auxiliary electrode CMTL is provided in common for a plurality of pixels. In other words, the common electrode CMTL has an opening OP. The opening OP is provided so as to expose the pixel electrode PTCO. A pattern of the opening OP is arranged inside a pattern of the pixel electrode PTCO. A region in which the opening OP is arranged corresponds to a display region. That is, the opening ZCON is included in the display region. The display region means a region where a user can visually recognize light from a pixel. For example, a region shielded by a metal layer and not visible to the user is not included in the display region. That is, the display region may be referred to as a “light transmitting region (or an opening region).”

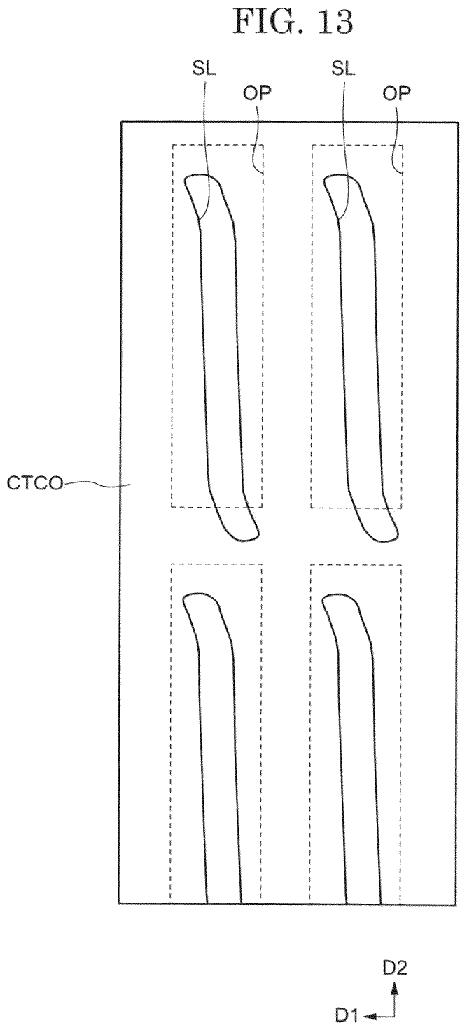

As shown in FIG. 13, the common electrode CTCO is commonly provided for a plurality of pixels. A slit SL is arranged in a region corresponding to the opening OP. The slit SL has a curved shape (a longitudinally long S-shape). An end of the slit SL has a shape in which a width perpendicular to an extension direction of the end is reduced. Referring to FIG. 1 and FIG. 13, the common electrode CTCO has the slit SL at a position facing the pixel electrode PTCO.

### [1-5. Configuration of Transistor Tr1]

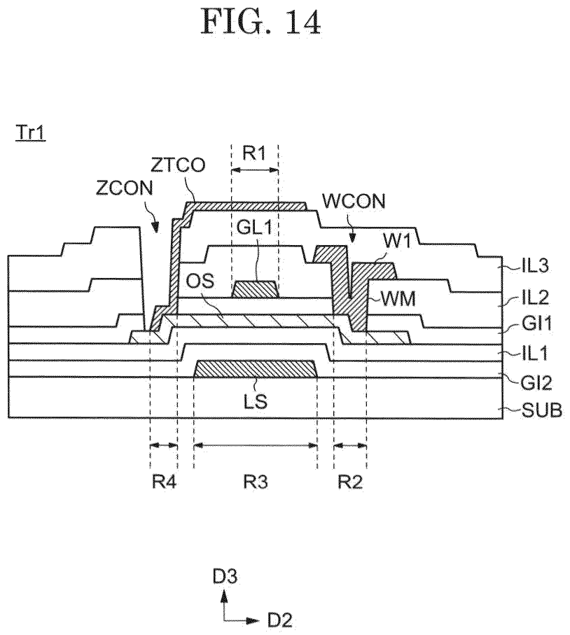

The structure of the transistor Tr1 of FIG. 1 will be described with reference to FIG. 14. In FIG. 14, the gate electrode LS is shown as a single layer for convenience of explanation. The transistor Tr1 in FIG. 14 is the same as the transistor Tr1 in FIG. 1. Therefore, a description that overlaps the description of FIG. 1 will be omitted.

As shown in FIG. 14, a region where the gate electrode GL1 and the oxide semiconductor layer OS overlap in the plan view is referred to as a region R1. A region in which the connection electrode WM and the oxide semiconductor layer OS are in contact with each other in the plan view is referred to as a region R2. A region where the gate electrode LS and the oxide semiconductor layer OS overlap in the plan view is referred to as a region R3. A region in which the connection electrode ZTCO and the oxide semiconductor layer OS are in contact with each other in the plan view is referred to as a region R4. The region R1 may be referred to as a “first region.” The region R2 may be referred to as a “second region.” The region R3 may be referred to as a “third region.” The region R4 may be referred to as a “fourth region.” As shown in FIG. 2 and FIG. 14, the direction D1 in which the gate electrode GL1 extends in the plan view may be referred to as a “first direction.” The direction D2 intersecting the direction D1 may be referred to as a “second direction.”

The region R1 of the oxide semiconductor layer OS may be referred to as a channel region. A region other than the channel region in the oxide semiconductor layer OS may be referred to as a source region or a drain region. That is, in a region in which the oxide semiconductor layer OS is arranged, a region overlapping the gate electrode GL1 in the plan view is a channel region, and a region not overlapping the gate electrode GL1 in the plan view is a source region or a drain region. One or both of the source region and the drain region may be referred to as a “low resistance region.” The amount of an impurity contained in the oxide semiconductor layer OS of the source region and the drain region is larger than the amount of the impurity contained in the oxide semiconductor layer OS of the channel region. As will be described later, the impurity is implanted into the film of the oxide semiconductor layer OS by ion implantation. The amount of the impurity contained in the oxide semiconductor layers OS in the source region and the drain region is less than 5E19/cm³.

In other words, the gate electrode GL1 overlaps the oxide semiconductor layer OS in the first region (region R1) in the plan view with respect to the structure of the transistor Tr1. The connection electrode WM is in contact with the oxide semiconductor layer OS in the second region (region R2) in the plan view. The gate electrode LS overlaps the oxide semiconductor layer OS in the third region (region R3) in the plan view. The connection electrode ZTCO is in contact with the oxide semiconductor layer OS in the fourth region (region R4) in the plan view.

The transistor Tr1 shown in FIG. 14 has a channel length of 2 μm or less. In other words, in a cross-sectional view, a width of the gate electrode GL1 is 2 μm or less in the direction D2. Further, in the direction D2, lengths of a distance between a portion where the connection electrode WM is in contact with the oxide semiconductor layer OS and the channel region, and a distance between a portion where the connection electrode ZTCO is in contact with the oxide semiconductor layer OS and the channel region are 2 μm or less. In other words, in the cross-sectional view, a distance between the region R1 and the region R2 in the direction D2 and a distance between the region R1 and the region R4 in the direction D2 are 2 μm or less. The region R2 may be included in the source region, the region R4 may be included in the drain region, the region R2 may be included in the drain region, and the region R4 may be included in the source region. An end portion of the connection electrode ZTCO is located at a bottom portion of the opening ZCON, and a portion of the oxide semiconductor layer OS is exposed from the connection electrode ZTCO at the bottom portion of the opening ZCON.

As described above, in the transistor Tr1, lengths of the source region and the drain region in the direction D2 from the channel region to the connection electrode are 2 μm or less. Therefore, even in the case where resistance of the oxide semiconductor layers OS in the source region and the drain region is high, an effect of the resistance of the oxide semiconductor layer OS on electric properties of the transistor Tr1 is small. Therefore, in order to reduce the resistance of the oxide semiconductor layers OS in the source region and the drain region, the amount of the impurity (ions) implanted into the oxide semiconductor layer OS can be reduced. In the ion implantation, the impurity is implanted into the oxide semiconductor layer OS, or an oxygen vacancy is formed in the oxide semiconductor layer OS when the impurity penetrates through the oxide semiconductor layer OS. On the other hand, when the impurity is implanted into the gate insulating layer GI1 and the gate insulating layer IL1, or when the impurity penetrates through the gate insulating layer GI1 and the gate insulating layer IL1, hydrogen is generated in these insulating layers. An effective channel length is reduced by diffusing this hydrogen to the oxide semiconductor layer OS in the channel region. If the amount of impurities to be ion-implanted is reduced, the amount of hydrogen generated from the gate insulating layer GI1 and the gate insulating layer IL1 is reduced, so that hydrogen is prevented from being circulated in the ion implantation into the oxide semiconductor layer OS in the channel region and from being diffused by heat treatment. Therefore, even in the case of the short channel transistor, it is possible to suppress the occurrence of an abnormal value in initial characteristics.

As described above, the gate electrode LS overlaps the oxide semiconductor layers OS of the source region and the drain region in the region R3. In the direction D2, the gate electrode LS is longer than the gate electrode GL1. Therefore, in the direction D2, a distance between the region R3 and the region R2 is smaller than the distance between the region R1 and the region R2. Similarly, in the direction D2, a distance between the region R3 and the region R4 is less than the distance between the region R1 and the region R4.

The gate electrode LS is supplied with the same voltage as the gate electrode GL1. Therefore, when an on-voltage is applied to the gate electrode GL1 in order to switch the transistor Tr1 from an off-state to an on-state, the on-voltage is also applied to the gate electrode LS. Consequently, not only in the oxide semiconductor layer OS in the channel region but also in the oxide semiconductor layers OS in the source region and the drain region which overlaps the gate electrode LS in the plan view, carriers are generated due to the electric field formed by the gate electrode LS.

Therefore, in the case where an on-voltage is applied to the gate electrode GL1 even if resistances of the oxide semiconductor layers OS in the source region and the drain region are high in a state where no voltage is applied to the gate electrode GL1, resistance of the oxide semiconductor layer OS in the region overlapping the gate electrode LS in the plan view is low. Therefore, the amount of the impurity to be ion-implanted into the oxide semiconductor layer OS can be reduced.

### [1-6. Short Channel Length Transistor]

The amount of excess oxygen contained in an insulating layer (high-temperature insulating layer) formed at a high temperature (for example, 350° C.) is smaller than the amount of excess oxygen contained in an insulating layer (low-temperature insulating layer) formed at a low temperature (for example, 200° C.). Therefore, the amount of oxygen released by the heat treatment is smaller in the high-temperature insulating layer than in the low-temperature insulating layer. Therefore, when a high-temperature insulating layer is used as a passivation layer (the insulating layer IL2 in FIG. 1) arranged above the gate electrode in the top-gate transistor in which the oxide semiconductor layer is used as the channel, it is not possible to secure a sufficiently large amount of oxygen supplied from the passivation layer to the oxide semiconductor layer. Therefore, the oxygen deficiency formed in the oxide semiconductor layer OS cannot be repaired in the manufacturing method. Therefore, in such a transistor, an abnormality is likely to occur in the initial characteristics. This characteristic abnormality appears more pronounced in transistors with a channel length of 2 μm or less.

On the other hand, with respect to resistance to the stress test, resistance of the high-temperature insulating layer is higher than that of the low-temperature insulating layer. That is, in the case where the low-temperature insulating layer is used as the passivation layer, the threshold voltage of the transistor is greatly shifted in a positive direction due to, for example, a PBTS (Positive Bias Temperature Stress) test. On the other hand, in the case where the high-temperature insulating layer is used as the passivation layer, shifting due to a PBTS test is suppressed. Therefore, in a transistor in which the high-temperature insulating layer is used as the passivation layer and a gate length is 2 μm or less, it is necessary to realize a transistor in which an abnormality in initial characteristics does not occur.

### [1-7. Ion Implantation Amount Dependence in Short Channel Length Transistor]

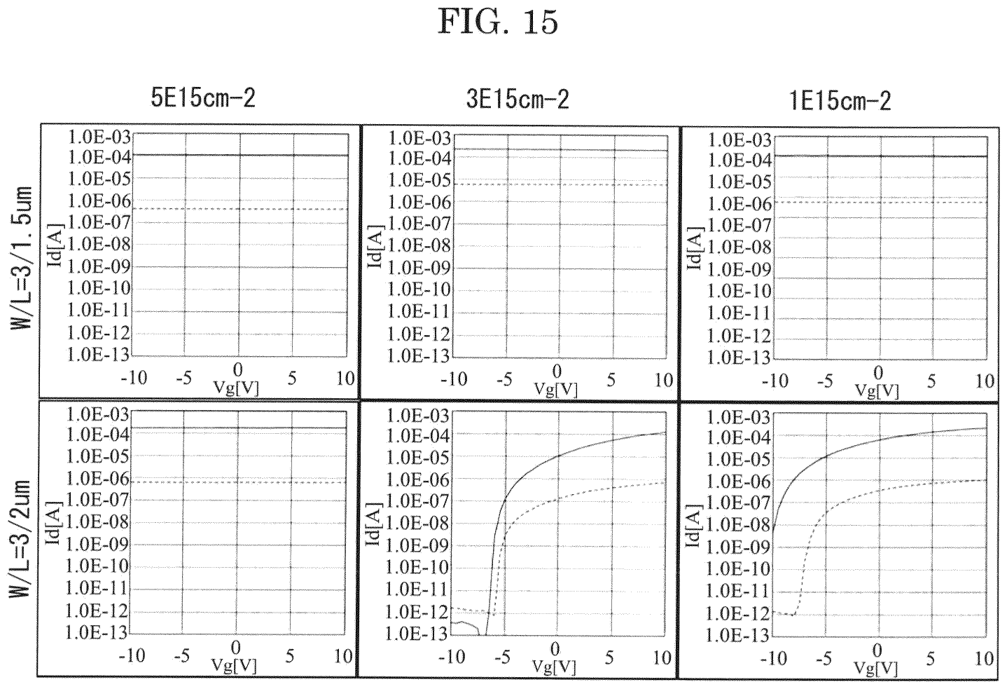

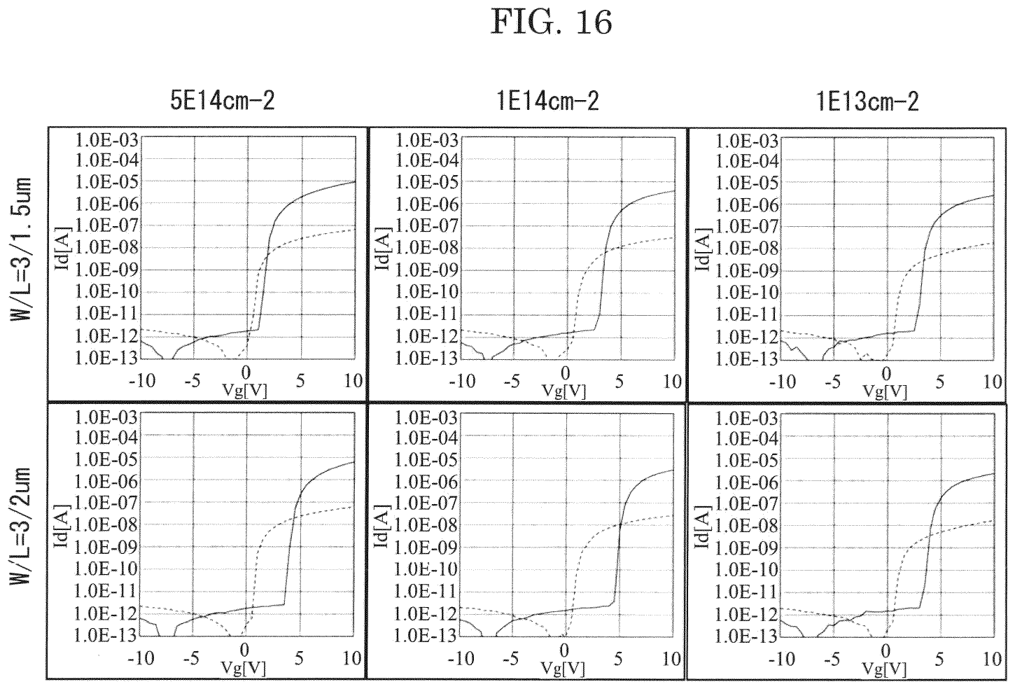

FIG. 15 and FIG. 16 show initial characteristics in the case where the high-temperature insulating layer is used as the insulating layer IL2 of the transistor Tr1 shown in FIG. 14. The electrical characteristics shown in FIG. 15 and FIG. 16 are electrical characteristics measured for a plurality of transistors Tr1 having varying ion implantation amounts for the oxide semiconductor layer OS. In FIG. 15 and FIG. 16, electric characteristics of an upper stage are the electric characteristic of the transistor Tr1 having a channel length of 1.5 μm, and electric characteristics of a lower stage are electric characteristics of the transistor Tr1 having a channel length of 2 μm.

Major processing requirements in the transistor Tr1 manufacturing method are as follows.
Oxide semiconductor layer OS thickness: 30 nm
Gate insulating layer GI1 thickness: 120 nm
Ion implantation amount: 1E13 to 5E15/cm²
Injection implantation acceleration voltage: 34 keV.
Film formation temperature of insulating layer IL2: 350° C.
Thickness of insulating layer IL2: 400 nm

In addition, the film formation temperature of the insulating layer IL2 is a set temperature in a chamber in which the substrate is arranged at the time of film formation.

The transistor Tr1 is measured as follows. A vertical axis of the respective electric properties represents the drain current value (Id[A]), and a horizontal axis represents the gate voltage value (Vg[V]). In the following, L means the channel length, and W means the width (channel width) of the channel region in a direction (direction D1 in FIG. 2) perpendicular to the channel length.
Size of channel regions: W/L=3 μm/1.5 μm or 3 μm/2 μm
Source drain voltage: 0.05 V (dotted line), 10.05 V (solid line)
Gate voltage: −10 V to +10 V
Measurement environment: room temperature, dark room

As shown in FIG. 15, in the case where the ion implantation amount is 1E15/cm² or more, an abnormality occurs in the initial characteristics. Characteristic abnormalities are more pronounced in the condition of L=1.5 μm than in the condition of L=2 μm. As will be described later, in the present embodiment, the impurity ions are implanted into the oxide semiconductor layer OS using the gate electrode GL1 as a mask. In the case where the ion implantation amount is large, hydrogen generated by the ion implantation is circulated below the gate electrode GL1, or hydrogen is diffused below the gate electrode GL1 by the heat treatment after the ion implantation, thereby reducing the effective channel length. The larger the ion implantation amount, the smaller the effective channel length. Therefore, it is considered that the characteristic abnormality appeared more remarkable in the condition of L=1.5 μm than in the condition of L=2 μm.

On the other hand, as shown in FIG. 16, even under the condition of L=2 μm and the condition of L=1.5 μm, if the ion implantation amount is 5E14/cm² or less, no abnormality occurs in the initial characteristics. That is, under the condition in which the ion implantation amount is 5E14/cm² or less, the phenomenon in which hydrogen generated by the ion implantation circulates below the gate electrode GL1 and the phenomenon in which hydrogen diffuses below the gate electrode GL1 by the heat treatment after the ion implantation are suppressed.

As the amount of the impurity due to the ion implantation decreases, the electric resistance of the oxide semiconductor layer OS in the source drain region increases. In the case where the electric resistance is large, the current flowing through the transistor Tr1 is limited by the electric resistances of the oxide semiconductor layers OS in the source region and the drain region. As a result, in the initial characteristics, there may be a problem that an on-state current reaches a peak (on-state current is saturated).

However, as shown in FIG. 16, the on-state current does not peak at the initial characteristics of the transistor Tr1. In the transistor Tr1, it is considered that one of the factors is that a distance from the connection electrode (the connection electrode WM and the connection electrode ZTCO) in contact with the oxide semiconductor layer OS to the channel region is 2 μm or less. Further, when an on-voltage is supplied to the gate electrode LS, since the gate electrode LS overlaps the oxide semiconductor layer OS of the source region and the drain region in the plan view, carriers caused by the electric field formed by the gate electrode LS are generated in the oxide semiconductor layer OS that overlaps the gate electrode LS. Therefore, since the electric resistance of the oxide semiconductor layer OS overlapping the gate electrode LS is reduced in the plan view, it is considered that the on-state current described above does not stop.

### [1-8. Method for Manufacturing Transistor Tr1]

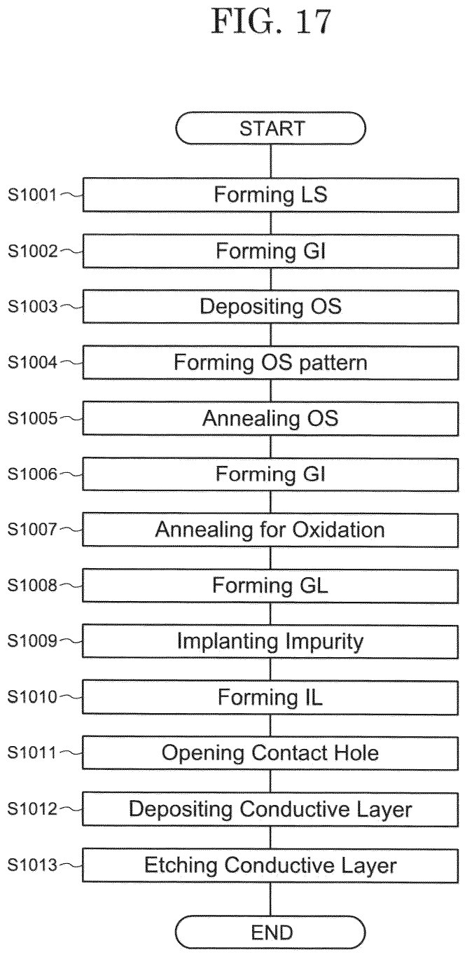

The transistor Tr1 according to the present embodiment will be described with reference to FIG. 14 and FIG. 17. FIG. 17 is a flowchart showing a method for manufacturing a semiconductor device according to an embodiment of the present invention.

As shown in FIG. 14 and FIG. 17, first, the gate electrode LS is formed on the substrate SUB (step S1001; Forming LS). The gate insulating layers GI2 and IL1 are formed on the gate electrode LS (step S1002; Forming GI), and an oxide semiconductor layer OS is formed on the entire surface (step S1003; Depositing OS). The oxide semiconductor layer OS is patterned by a photolithography process and an etching process for the oxide semiconductor layer OS (step S1004; Forming OS pattern). The patterned oxide semiconductor layer OS is subjected to a heat treatment (step S1005; Annealing OS).

Next, the gate insulating layer GI1 is formed on the oxide semiconductor layer OS (step S1006; Forming GI). With the gate insulating layer GI1 formed over the entire surface, oxidation annealing is performed on the oxide semiconductor layer OS (step S1007; Annealing for Oxidation). Many oxygen vacancies occur on the upper surface and the side surface of the oxide semiconductor layer OS in a process from the formation of the oxide semiconductor layer OS to the formation of the gate insulating layer GI1 on the oxide semiconductor layer OS. By the oxidation annealing, for example, oxygen released from the gate insulating layer IL1 is supplied to the oxide semiconductor layer OS, and the oxygen vacancy is repaired.

Next, a conductive layer is formed on the gate insulating layer GI1. The conductive layer is formed on the entire surface. As shown in FIG. 2, the gate electrode GL1 extending in the direction D1 is formed by a photolithography process and an etching process for the conductive layer (step S1008; Forming GL). In a state where the gate electrode GL1 is formed, the ion implantation of an impurity is performed on the source region and the drain region of the oxide semiconductor layer OS (the region corresponding to OS2 of FIG. 1) (step S1009; Implanting Impurity).

Specifically, in S1009, the impurity is implanted into the oxide semiconductor layer OS from the gate electrode GL1 through the gate insulating layer GI1 by the ion implantation. The impurities implanted by the ion implantation are 5E14/cm² or less. For example, at least one element of argon (Ar), phosphorus (P), and boron (B) is implanted into the oxide semiconductor layer OS as the impurity by ion implantation. Other than the above, as the impurity, at least one element among hydrogen (H), helium (He), lithium (Li), beryllium (Be), carbon (C), nitrogen (N), neon (Ne), sodium (Na), magnesium (Mg), aluminum (Al), silicon (Si), sulfur(S), potassium (K), calcium (Ca), scandium (Sc), titanium (Ti), vanadium (V), chromium (Cr), manganese (Mn), iron (Fe), cobalt (Co), nickel (Ni), copper (Cu), germanium (Ge), arsenic (As), selenium (Se), krypton (Kr), xenon (Xe), strontium (Sr), yttrium (Y), zirconium (Zr), niobium (Nb), molybdenum (Mo), silver (Ag), tin (Sn), antimony (Sb), tellurium (Te), cesium (Cs), barium (Ba), hafnium (Hf), tantalum (Ta), tungsten (W), gold (Au), and bismuth (Bi) may be implanted as the impurity into the oxide semiconductor layer OS. Oxygen vacancies are formed in the oxide semiconductor layer OS by the ion implantation, and the oxygen vacancies are bonded to hydrogen in a subsequent heat treatment, thereby reducing the resistance of the oxide semiconductor layer OS. Since the gate electrode GL1 is arranged above the oxide semiconductor layer OS which functions as a channel region of the transistor Tr1, the impurity is not implanted into the oxide semiconductor layer OS in the channel region.

Next, the insulating layer IL2 is formed on the gate electrode GL1 (step S1010; Forming IL). Next, the opening WCON is formed in the insulating layer IL2 and the gate insulating layer GI1 (step S1011; Opening Contact Hole). A portion of the oxide semiconductor layer OS is exposed by the opening WCON formed by the contact opening. A conductive layer is deposited on the insulating layer IL2 and inside the contact (step S1012; Depositing Conductive Layer).

Next, a mask is formed in the region where the wiring W1 is arranged, and the conductive layer formed over the entire surface is etched through the mask (step S1013; Etching Conductive Layer). Subsequent to the above steps, the same steps as those in S1010 to S1013 are repeated, whereby the insulating layer IL3 is formed, the opening ZCON is formed on the insulating layer IL3, and the connection electrode ZTCO is formed, thereby completing the configuration shown in FIG. 14.

### [1-9. Material of Each Member of Display Device 10]

As the substrate SUB, a rigid substrate having translucency and no flexibility, such as a glass substrate, a quartz substrate, and a sapphire substrate, can be used. On the other hand, in the case where the substrate SUB needs to have flexibility, a flexible substrate including a resin such as a polyimide substrate, an acryl substrate, a siloxane substrate, or a fluorine resin substrate having flexibility can be used as the substrate SUB. In order to improve the heat resistance of the substrate SUB, the resin may be doped with the impurity.

A common metallic material can be used as the gate electrodes LS, GL1, and GL2, the wirings W1 and W2, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), and silver (Ag), or alloys or compounds thereof are used as the members of these electrodes. As a member such as the electrode described above, the material described above may be used as a single layer or may be used as a laminate.

For example, a laminate of Ti/Al/Ti is used as the gate electrode GL1. In the present embodiment, a cross-sectional shape of patterned end portions of the gate electrode GL1 having the laminate described above is a forward-tapered shape.

A common insulating layer can be used as the gate insulating layers GI1, GI2, and IL1 and the insulating layers IL2 to IL5. For example, an inorganic insulating layer such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) can be used as the gate insulating layers GI1, GI2, and IL1 and the insulating layers IL2, IL3, and IL5. An insulating layer with few defects can be used as these insulating layers. An organic insulating material such as a polyimide resin, an acryl resin, an epoxy resin, a silicone resin, a fluorine resin, or a siloxane resin can be used as the insulating layer IL4. The organic insulating material described above may be used as the gate insulating layers GI1, GI2, and IL1 and the insulating layers IL2, IL3, and IL5. A material of the insulating layer described above may be used as a single layer or may be used as a laminate.

As an exemplary insulating layer, SiOₓ having a thickness of 120 nm is used as the gate insulating layer GI1. SiOₓ/SiNₓ/SiOₓ having a total thickness of 300 nm to 700 nm is used as the gate insulating layer IL1. SiOₓ/SiNₓ having a total thickness of 60 to 150 nm is used as the gate insulating layer GI2. SiOₓ having a total thickness of 300 nm to 500 nm is used as the insulating layer IL2. SiOₓ (single layer), SiNₓ (single layer), or a stack thereof having a total thickness of 200 nm to 500 nm is used as the insulating layer IL3. An organic layer having a thickness of 2 μm to 4 μm is used as the insulating layer IL4. SiNₓ (single layer) having a thickness of 50 nm to 150 nm is used as the insulating layer IL5.

SiOₓN_{y} and AlOₓN_{y} are silicon-containing and aluminum-containing compounds that contain a smaller proportion (x>y) of nitrogen (N) than oxygen (O). SiNₓO_{y} and AlNₓO_{y} are silicon-containing and aluminum-containing compounds that contain a lower proportion (x>y) of oxygen than nitrogen.

A metal oxide having semiconductor properties can be used as the oxide semiconductor layer OS. For example, an oxide semiconductor containing indium (In), gallium (Ga), zinc (Zn), and oxygen (O) can be used as the oxide semiconductor OS. For example, an oxide semiconductor having a composition ratio of In:Ga:Zn:O=1:1:1:4 can be used as the oxide semiconductor layer OS. However, the oxide semiconductor containing In, Ga, Zn, and O used in the present embodiment is not limited to the composition described above, and an oxide semiconductor having a composition other than the composition described above may be used. For example, an oxide semiconductor layer having a higher ratio of In than those described above may be used in order to improve mobility. On the other hand, in order to increase the bandgap and reduce an effect of light irradiation, an oxide semiconductor layer having a Ga ratio larger than the ratio described above may be used.

For example, an oxide semiconductor containing two or more metals containing indium (In) may be used as the oxide semiconductor layer OS having an In ratio higher than that described above. In the oxide semiconductor layer OS, the ratio of the indium element to the total metal element may be 50% or more in atomic ratio. In addition to indium, gallium (Ga), zinc (Zn), aluminum (Al), hafnium (Hf), yttrium (Y), zirconia (Zr), and lanthanoids may be used as the oxide semiconductor layer OS. An element other than the above may be used as the oxide semiconductor layer OS.

Other elements may be added to the oxide semiconductor containing In, Ga, Zn, and O as the oxide semiconductor layers OS. For example, a metallic element such as Al or Sn may be added to the oxide semiconductor. In addition to the oxide semiconductor described above, an oxide semiconductor (IGO) containing In and Ga, an oxide semiconductor (IZO) containing In and Zn, an oxide semiconductor (ITZO) containing In, Sn, and Zn, an oxide semiconductor containing In and W, and the like may be used as the oxide semiconductor layer OS.

Although a detailed method for manufacturing the oxide semiconductor layer OS will be described later, the oxide semiconductor layer OS can be formed using a sputtering method. Compositions of the oxide semiconductor layer OS formed by the sputtering method depend on compositions of a sputtering target. The composition of the metal element in the oxide semiconductor layer OS can be specified based on the composition of the metal element of the sputtering target.

As described above, transparent conductive layers are used as the connection electrode ZTCO, the wiring XTCO, the pixel electrode PTCO, and the common electrode CTCO. Mixtures of ITO and indium oxide and zinc oxide (IZO) can be used as the transparent conductive layers. A material other than the above may be used as the transparent conductive layer.

As described above, in the case where a metal oxide layer is arranged between the oxide semiconductor layer OS and the gate insulating layer IL1, a metal oxide containing aluminum as a main component is used as the metal oxide layer. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer. The “metal oxide layer containing aluminum as a main component” means that a ratio of aluminum contained in the metal oxide layer is 1% or more of a total amount of the metal oxide layer. The ratio of aluminum contained in the metal oxide layer may be 5% or more and 70% or less, 10% or more and 60% or less, or 30% or more and 50% or less of the entire metal oxide layer. The ratio may be a mass ratio or a weight ratio.

As described above, according to the structure of the transistor Tr1 and the manufacturing method thereof according to the present embodiment, it is possible to realize a transistor Tr1 which exhibits good initial characteristics even if the channel length is 2 μm or less in the transistor Tr1 in which a high-temperature insulating layer having high resistance to stress testing is used as the insulating layer IL2.

Further, according to the transistor Tr1 of the present embodiment, the oxide semiconductor layer OS and the connection electrode ZTCO which is the transparent conductive layer are brought into direct contact with each other, thereby ensuring conduction between them. Therefore, there is no need to provide a metallic layer between the oxide semiconductor layer OS and the connection electrode ZTCO. Further, according to the transistor Tr1 of the present embodiment, the contact resistance between the oxide semiconductor layer OS and the connection electrode ZTCO can be reduced. Therefore, the process margin can be increased without deteriorating the electric properties of the transistor Tr1.

According to the configuration described above, since the light is not blocked in the opening ZCON, it is possible to suppress a decrease in the aperture ratio. The oxide semiconductor layer has a light transmitting property. Therefore, in the present embodiment, although the oxide semiconductor layer is provided in the opening region of the pixel region, the light from the backlight passes through the oxide semiconductor layer. Therefore, a decrease in transmittance of the opening region due to the oxide semiconductor layer being provided in the opening region is suppressed. The oxide semiconductor layer OS has a light transmitting property, and therefore, unlike the silicon layer, is unlikely to cause unevenness in transmitted light. Since the oxide semiconductor layer OS is provided in the display region, generation of display unevenness can be suppressed.

### [1-10. Modification]

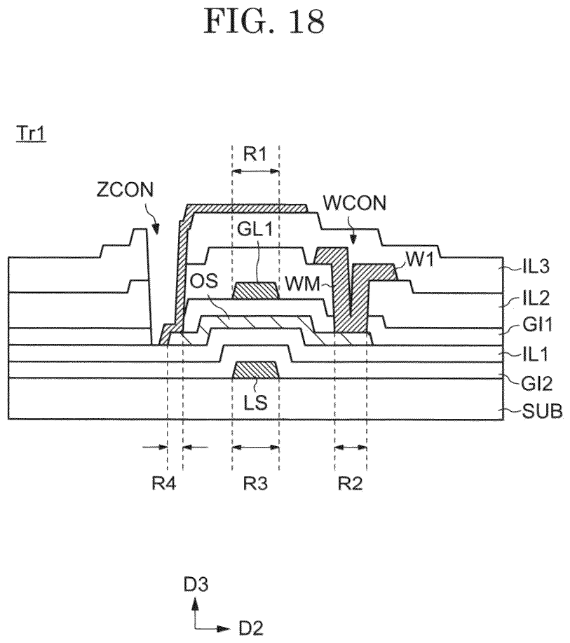

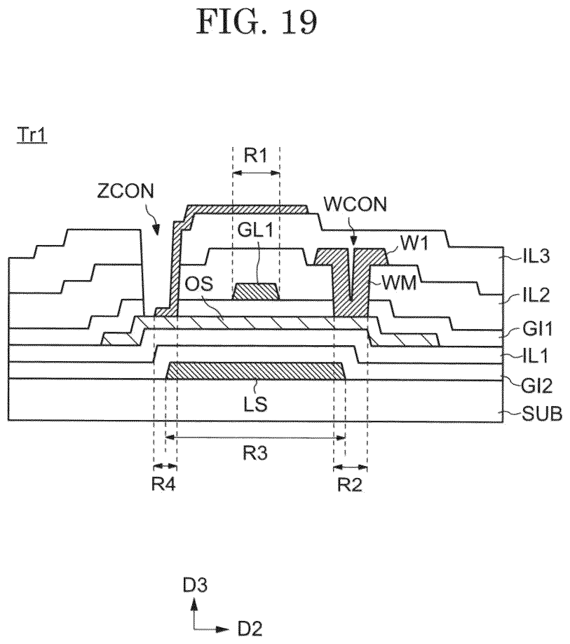

A modification of the first embodiment will be described with reference to FIG. 18 and FIG. 19. FIG. 18 and FIG. 19 are cross-sectional views showing a structure of a semiconductor device according to a modification of the embodiment of the present invention. FIG. 18 and FIG. 19 are diagrams corresponding to FIG. 14. Although the cross-sectional structure shown in FIG. 18 and FIG. 19 is similar to the cross-sectional structure shown in FIG. 14, in FIG. 14, FIG. 18, and FIG. 19, lengths of the gate electrodes LS in the direction D2 are different from each other.

In the transistor Tr1 shown in FIG. 18, the length of the gate electrode LS is substantially the same as the length of the gate electrode GL1 in the direction D2. That is, in the direction D2, the distance between the region R3 and the region R2 is substantially the same as the distance between the region R1 and the region R2. Similarly, in the direction D2, the distance between the region R3 and the region R4 is substantially the same as the distance between the region R1 and the region R4.

As described above, even in the case where the gate electrode LS does not overlap the source region and the drain region in the plan view, since the distance from the connection electrode (the connection electrode WM and the connection electrode ZTCO) in contact with the oxide semiconductor layer OS to the channel region is 2 μm or less, good initial characteristics can be obtained even if the implantation amount of the impurity into the oxide semiconductor layer OS is 5E14/cm² or less.

In the transistor Tr1 shown in FIG. 19, the gate electrode LS is provided up to a region reaching the opening WCON and the opening ZCON in the direction D2. In other words, the region R3 overlaps the region R2 in the plan view. Similarly, the region R3 overlaps the region R4 in the plan view. That is, when an on-voltage is applied to the gate electrode LS, carriers caused by the electric field formed by the gate electrode LS are generated in the oxide semiconductor layer OS between the channel region and the connection electrode (the connection electrode WM and the connection electrode ZTCO), and therefore, even in the case where the amount of the impurity implanted in the source region and the drain region is smaller than those described above, good initial characteristics can be obtained.

### 2. Second Embodiment

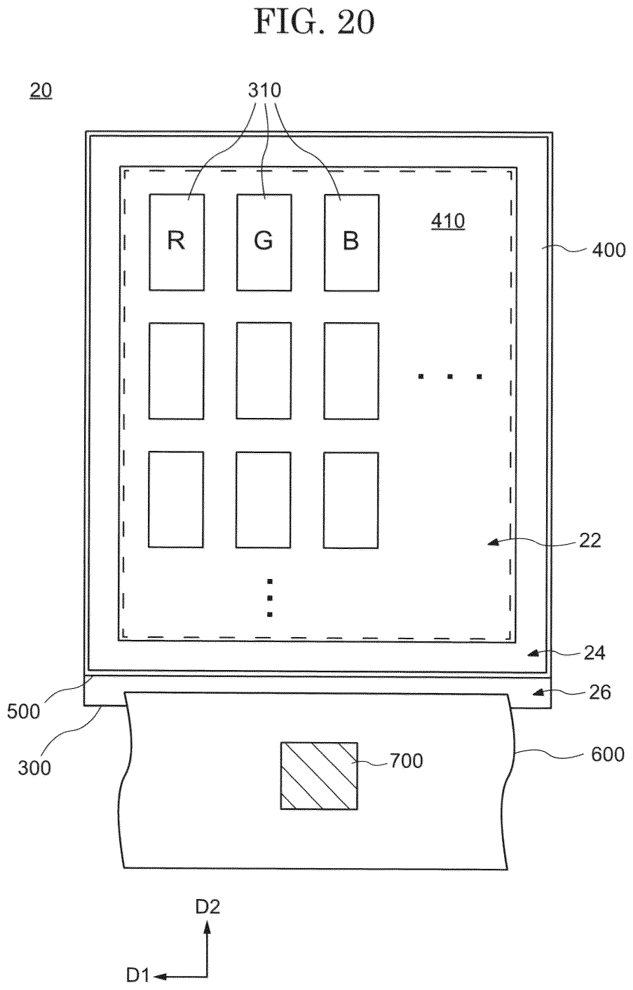

With reference to FIG. 20 to FIG. 22, the overall configuration of the display device described in the first embodiment will be described.

### [2-1. Overview of Display Device 20]

FIG. 20 is the plan view showing an outline of a display device according to an embodiment of the present invention. As shown in FIG. 20, a display device 20 includes an array substrate 300, a sealing portion 400, a counter substrate 500, a flexible printed circuit substrate 600 (FPC 600), and an IC chip 700. The array substrate 300 and the counter substrate 500 are bonded to each other by the sealing portion 400. In a liquid crystal region 22 surrounded by the sealing portion 400, a plurality of pixel circuits 310 are arranged in a matrix. The liquid crystal region 22 is a region overlapping the liquid crystal device 410 described later in the plan view. The liquid crystal region 22 is a region that contributes to display. The liquid crystal region 22 may be referred to as a “display region.” The transistor Tr1 is arranged in the liquid crystal region 22 (the display region).

A sealing region 24 in which the sealing portion 400 is arranged is a region around the liquid crystal region 22. The FPC 600 is arranged in a terminal region 26. The terminal region 26 is a region where the array substrate 300 is exposed from the counter substrate 500, and is provided outside the sealing region 24. In addition, an outside of the seal region 24 means an outside of the region where the sealing portion 400 is arranged and the region surrounded by the sealing portion 400. The IC chip 700 is arranged above the FPC 600. The IC chip 700 is configured to drive the pixel circuit 310. The sealing region 24 or a region in which the sealing region 24 and the terminal region 26 are combined is a region surrounding the liquid crystal region 22 (display region). These regions may be referred to as “frame regions.” The transistor Tr2 is provided in the frame region.

### [2-2. Circuit Configuration of Display Device 20]

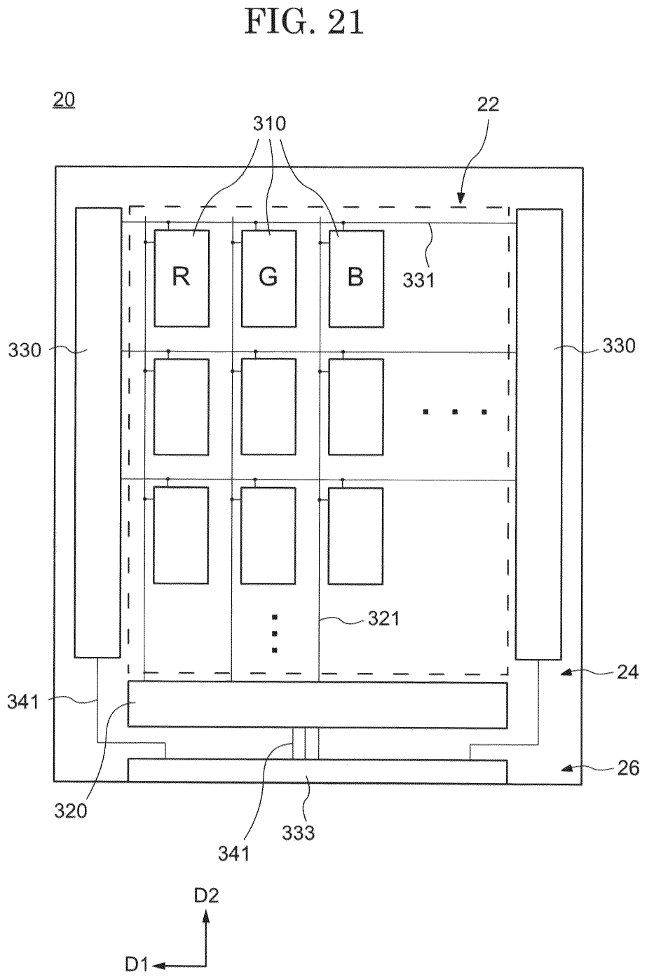

FIG. 21 is a block diagram showing a circuit configuration of a display device according to an embodiment of the present invention. As shown in FIG. 21, a source driver circuit 320 is arranged at a position adjacent to the liquid crystal region 22 where the pixel circuit 310 is disposed in the direction D2 (column direction), and a gate driver circuit 330 is provided at a position adjacent to the liquid crystal region 22 in the direction D1 (row direction). The source driver circuit 320 and the gate driver circuit 330 are arranged in the sealing region 24. However, the region in which the source driver circuit 320 and the gate driver circuit 330 are arranged is not limited to the sealing region 24, and any region may be used as long as it is outside the region in which the pixel circuit 310 is arranged.

A source line 321 extends from the source driver circuit 320 in the direction D2 and is connected to a plurality of pixel circuits 310 arranged in the direction D2. A gate line 331 extends from the gate driver circuit 330 in the direction D1 and is connected to a plurality of pixel circuits 310 arranged in the direction D1. The source wiring 321 corresponds to the wiring W1 of FIG. 2. The gate line 331 corresponds to the gate electrode GL1 of FIG. 2.

A terminal unit 333 is arranged in the terminal region 26. The terminal unit 333 and the source driver circuit 320 are connected by a connection wiring 341. Similarly, the terminal unit 333 and the gate driver circuit 330 are connected by the connection wiring 341. By the FPC 600 being connected to the terminal unit 333, an external device to which the FPC 600 is connected and the display device 20 are connected, and the respective pixel circuits 310 provided in the display device 20 are driven by signals from the external device.

The transistor Tr1 according to the first embodiment is used in the pixel circuit 310. The transistor Tr2 according to the first embodiment is applied to transistors included in the source driver circuit 320 and the gate driver circuit 330.

### [2-3. Pixel Circuit 310 of Display Device 20]

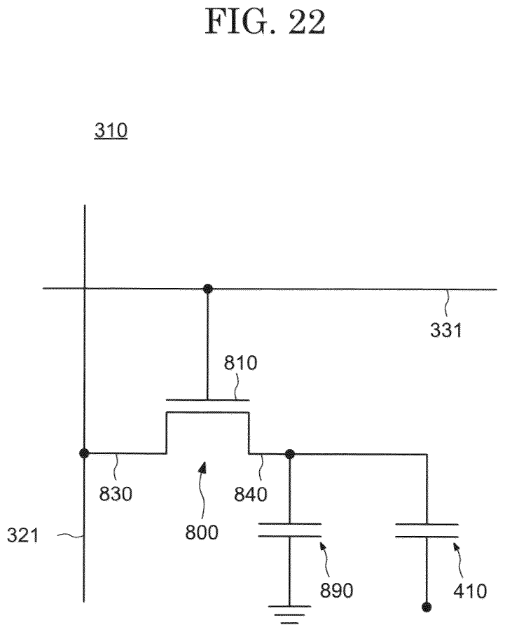

FIG. 22 is a circuit diagram showing a pixel circuit of a display device according to an embodiment of the present invention. As shown in FIG. 22, the pixel circuit 310 includes devices such as a transistor 800, a storage capacitor 890, and a liquid crystal device 410. One electrode of the storage capacitor 890 is the pixel electrode PTCO, and the other electrode is the common electrode CTCO. Similarly, one electrode of the liquid crystal device 410 is the pixel electrode PTCO, and the other electrode is the common electrode CTCO. The transistor 800 includes a first gate electrode 810, a first source electrode 830, and a first drain electrode 840. The first gate electrode 810 is connected to the gate wiring 331. The first source electrode 830 is connected to the source wiring 321. The first drain electrode 840 is connected to the storage capacitor 890 and the liquid crystal device 410. The transistor Tr1 shown in the first embodiment is applied to the transistor 800 shown in FIG. 22. In the present embodiment, for convenience of explanation, although 830 is referred to as a source electrode, and 840 is referred to as a drain electrode, the function as the source and the function as the drain of each electrode may be interchanged.

Each of the embodiments described above as the embodiment of the present invention can be appropriately combined as long as they are not mutually contradictory. Furthermore, the addition, deletion, or design change of components, or the addition, deletion, or condition change of processes as appropriate by those skilled in the art based on the semiconductor device of each embodiment are also included in the scope of the present invention as long as they are provided with the gist of the present invention.

It is understood that, even if the effect is different from those provided by each of the embodiments disclosed herein, the effect obvious from the description in the specification or easily predicted by a person skilled in the art is apparently derived from the present disclosure.

What is claimed is:

1. A semiconductor device comprising:
a first gate electrode;
a first gate insulating layer above the first gate electrode;
an oxide semiconductor layer above the first gate insulating layer;
a second gate insulating layer above the oxide semiconductor layer and having a first aperture and a second aperture reaching the oxide semiconductor layer;
a second gate electrode above the second gate insulating layer and extending in a first direction;
a first electrode in contact with the oxide semiconductor layer in the first aperture; and
a second electrode in contact with the oxide semiconductor layer in the second aperture,
wherein
the second gate electrode overlaps the oxide semiconductor layer in a first region,
the first electrode is in contact with the oxide semiconductor layer in a second region,
a width of the second gate electrode in a second direction intersecting the first direction is 2 μm or less in a cross-sectional view, and
a distance between the first region and the second region in the second direction is 2 μm or less in the cross-sectional view.

2. The semiconductor device according to claim 1, wherein
the first gate electrode overlaps the oxide semiconductor layer in a third region, and
a distance between the third region and the second region in the second direction is smaller than the distance between the first region and the second region in the second direction in the cross-sectional view.

3. The semiconductor device according to claim 2, wherein
the second electrode is in contact with the oxide semiconductor layer in a fourth region,
a distance between the first region and the fourth region in the second direction is 2 μm or less in the cross-sectional view,
a distance between the third region and the fourth region in the second direction is smaller than the distance between the first region and the fourth region in the second direction in the cross-sectional view,
the first electrode is a metal layer, and
the second electrode is a transparent conductive layer.

4. The semiconductor device according to claim 3, further comprising:
a first insulating layer above the second gate electrode; and
a second insulating layer above the first insulating layer,
wherein
the first aperture is provided in the second gate insulating layer and the first insulating layer,
the second aperture is provided in the second gate insulating layer, the first insulating layer, and the second insulating layer,
the first electrode is provided between the first insulating layer and the second insulating, and
the second electrode is provided above the second insulating layer.

5. The semiconductor device according to claim 1, wherein
the first gate electrode overlaps the oxide semiconductor layer in a third region in a plan view, and
a part of the third region overlaps the second region in a plan view.

6. The semiconductor device according to claim 5, wherein
the second electrode is in contact with the oxide semiconductor layer in a fourth region,
a distance between the first region and the fourth region in the second direction is 2 μm or less in the cross-sectional view,
a part of the third region overlaps the fourth region in the plan view,
the first electrode is a metal layer, and
the second electrode is a transparent conductive layer.

7. The semiconductor device according to claim 6, further comprising:
a first insulating layer above the second gate electrode; and
a second insulating layer above the first insulating layer,
wherein
the first aperture is provided in the second gate insulating layer and the first insulating layer,
the second aperture is provided in the second gate insulating layer, the first insulating layer, and the second insulating layer,
the first electrode is provided between the first insulating layer and the second insulating, and
the second electrode is provided above the second insulating layer.

8. The semiconductor device according to claim 1, wherein
the oxide semiconductor layer is divided into:
a channel region overlapping the second gate electrode in a plan view; and
a low resistance region not overlapping the second gate electrode in the plan view,
an amount of an impurity included in the oxide semiconductor layer in the low resistance region is larger than an amount of the impurity included in the oxide semiconductor layer in the channel region, and
the amount of the impurity included in the oxide semiconductor layer in the low resistance region is less than 5E19/cm³.

9. A method for manufacturing a semiconductor device comprising:
forming a first gate electrode above a substrate;
forming a first gate insulating layer above the first gate electrode;
forming an oxide semiconductor layer above the first gate insulating layer;
forming a second gate insulating layer above the oxide semiconductor layer;
forming a second gate electrode above the second gate insulating layer, the second gate electrode extending in a first direction;
implanting an impurity to the oxide semiconductor layer through the second gate insulating layer from above the second gate electrode;
forming a first aperture and a second aperture in the second gate insulating layer, the first aperture and the second aperture reaching the oxide semiconductor; and
forming a first electrode in contact with the oxide semiconductor in the first aperture and a second electrode in contact with the oxide semiconductor in the second aperture,
wherein
a width of the second gate electrode in a second direction intersecting the first direction is 2 μm or less in a cross-sectional view, and
a distance between the first region and the second region in the second direction is 2 μm or less in the cross-sectional view.

10. The method for manufacturing semiconductor device according to claim 9, wherein amount of the impurity is 5E14/cm² or less.
